(19) United States
(12) Patent Application Publication
(10) Pub. No.: US 2017/0298503 A1
(43) Pub. Date: Oct. 19, 2017

(54) COMBINED ANNEAL AND SELECTIVE DEPOSITION SYSTEMS

(71) Applicant: ASM IP Holding B.V., Almere (NL)

(72) Inventors: Jan Willem MAES, Wilrijk (BE); Werner KNAEPEN, Leuven (BE)

(21) Appl. No.: 15/132,084

(22) Filed: Apr. 18, 2016

(51) Int. Cl. C23C 16/04; H01L 21/67; C23C 16/40; C23C 16/06; C23C 16/36; C23C 16/30

(52) U.S. Cl. CPC C23C 16/04; H01L 21/67207; H01L 21/67103; C23C 16/405; C23C 16/403; C23C 16/06; C23C 16/36; C23C 16/308; C23C 16/303; C23C 16/402

(57) ABSTRACT

A system and a method for forming a film with an annealing step and a deposition step is disclosed. The system performs an annealing step for inducing self-assembly or alignment within a polymer. The system also performs a selective deposition step in order to enable selective deposition on a polymer.

### CROSS-REFERENCE TO RELATED APPLICATION

This application is related to U.S. Provisional patent application Ser. No. ______, filed Apr. 18, 2016 and entitled “METHOD OF FORMING A DIRECTED SELF-ASSEMBLED LAYER ON A SUBSTRATE,” attorney docket no. IMEC928.001PRF, and U.S. Non-Provisional patent application Ser. No. ______, filed Apr. 18, 2016 and entitled “COMBINED ANNEAL AND SELECTIVE DEPOSITION PROCESS,” attorney docket no. IMEC929.001AUS, the disclosures of which are hereby incorporated by reference in their entireties.

### FIELD

The present disclosure generally relates to systems for manufacturing electronic devices. More particularly, the disclosure relates to selective deposition of films. Specifically, the disclosure may disclose systems to selectively form films using a directed self-assembly (DSA) patterning technique.

### BACKGROUND

As the trend has pushed semiconductor devices to smaller and smaller sizes, different patterning techniques have arisen. These techniques include spacer defined quadruple patterning, extreme ultraviolet lithography (EUV), and EUV combined with Spacer Defined Double patterning. These approaches have allowed production of nodes in the 7 nm range.

Directed self-assembly (DSA) has been considered as an option for future lithography applications. DSA involves the use of block copolymers to define patterns for self-assembly. The block copolymers used may include poly(methyl methacrylate) (PMMA), polystyrene, or poly(styrene-block-methyl methacrylate) (PS-b-PMMA). Other block copolymers may include emerging “high-Chi” polymers, which may potentially enable small dimensions.

DSA can be used to form parallel lines or regular arrays of holes/pillars/posts with very small pitch and critical dimensions. In particular, DSA can define sub-20 nm patterns through self-assembly, while guided by surface topography and/or surface chemical patterning. As a result, a DSA polymer layer can be infiltrated with a precursor, or a film may be deposited selectively on one of the polymers of the DSA layers.

However, the DSA technique has several drawbacks. In particular, DSA polymers, such as PMMA or polystyrene, have low etch resistance. This makes the transfer of the pattern to layers below more difficult. The issue of low etch resistance becomes greater when the advanced polymers needed to further downscale the size of the semiconductor device has an even lower etch resistance and etch selectivity. In addition, the DSA may result in a high line edge roughness in the obtained patterns. Another drawback is that the obtained structure of parallel lines or array of holes may have some defects at random locations.

As a result, a system for selectively forming a film with higher etching resistance and etching selectivity is desired.

### SUMMARY OF THE DISCLOSURE

In accordance with at least one embodiment of the invention, a system configured to selectively form a film is disclosed. The system may comprise: a reaction chamber, the reaction chamber configured to hold at least one substrate having at least one polymer layer; a heating element configured to perform an annealing step on the at least one substrate; and a gas precursor delivery system, the gas precursor delivery system configured to perform a film deposition by sequentially pulsing a first precursor and a second precursor onto the substrate, the film deposition being configured to enable infiltration of at least the first precursor into the at least one polymer layer; wherein a film forms on the at least one polymer from the first precursor.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached FIGURES, the invention not being limited to any particular embodiment(s) disclosed.

### BRIEF DESCRIPTION OF THE DRAWINGS

These and other features, aspects, and advantages of the invention disclosed herein are described below with reference to the drawings of certain embodiments, which are intended to illustrate and not to limit the invention.

FIG. 1 is a flowchart in accordance with at least one embodiment of the invention.

It will be appreciated that elements in the figures are illustrated for simplicity and clarity and have not necessarily been drawn to scale. For example, the dimensions of some of the elements in the FIGURES may be exaggerated relative to other elements to help improve understanding of illustrated embodiments of the present disclosure.

### DETAILED DESCRIPTION OF EXAMPLE EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

Embodiments in accordance with the invention relate to the combination of DSA techniques with selective deposition. This combination can increase the etch resistance of polymers significantly. Selective deposition allows for particular polymers to be reacted with a precursor gas, while leaving other polymers untouched.

Combining selective deposition with DSA patterning may provide benefits previously unseen with prior approaches, such as the one described in US Patent Publication No. U.S. 2014/0273514 A1. For example, a selective deposition of aluminum oxide (Al₂O₃) at 90° C. may allow the reaction with a PMMA polymer, while leaving a polystyrene polymer untouched. The aluminum oxide will not only deposit on top of the PMMA polymer, but may be infused into the PMMA polymer to increase the rigidity of the PMMA polymer.

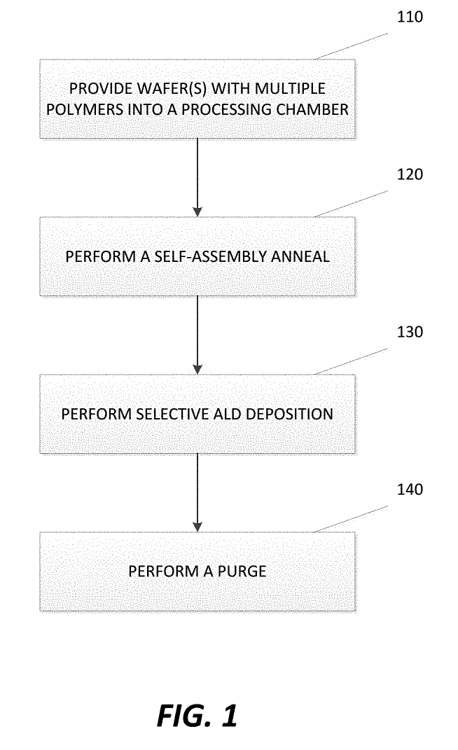

FIG. 1 illustrates a method 100 in accordance with at least one embodiment of the invention. The method 100 includes a first step 110 of providing a wafer with multiple polymers in a processing chamber. As described above, the wafer may have at least a first DSA polymer and a second DSA polymer, wherein the first DSA polymer and the second DSA polymer may be made of PMMA, polystyrene (PS), among other polymers. The processing chamber may be a batch reactor or a cluster tool with two batch reactors. One example of a potential processing chamber may include an A412™ system from ASM International N.V. of Bilthoven, The Netherlands, which may run in two reactor chambers the same process or run two different processes independently or sequentially.

The method 100 may include a second step 120 of performing a self-assembly anneal of the DSA polymers. The purpose of the annealing process is to incite the self-assembly or self-organization in the DSA polymers or the block copolymer. In other words, parallel lines or grids of holes/pillars/posts in the polymers may be formed as directed by guidance structures on the substrate. In accordance with at least one embodiment of the invention, this may mean that domains of PMMA and domains of PS may be formed in an alternating manner. The benefits achieved by the self-assembly anneal may include improvement of the self-assembly process, reduction of defects, improved line width roughness, and improved critical dimension (CD) uniformity. Alternatively, the anneal of the second step 120 may have a purpose of degassing moisture or other contaminants from the polymer, hardening the polymer, or selectively burning away one of the polymer types from the substrate surface.

In order to reach a low defect density in the obtained pattern, process parameters, such as the time, temperature, and the ambient conditions and pressure of the annealing process, are critical. A long annealing time may be needed to obtain a low defect density. The anneal may take place at a temperature ranging between 100° C. and 400° C., preferably between 200° C. and 300° C., and most preferably 250° C., for about 60 minutes. Other temperatures and durations are possible depending on the amount of anneal desired. However, the temperature of the self-assembly anneal should not be increased too high or the polymers may start to decompose.

The ambient environment in which the annealing is done may comprise nitrogen, argon, helium, hydrogen, oxygen, ozone, water vapor, solvent vapors, or mixtures of these gases. The pressure of the anneal ambient environment can be any pressure in the range from ultra-high vacuum to atmospheric pressure or even above atmospheric pressure.

In accordance with one embodiment of the invention, the annealing process may take place on a single wafer hot plate. In accordance with another embodiment of the invention, a batch reactor may prove to be beneficial for processes needing a long anneal time. The batch reactor may hold between 2 and 250 substrates, preferably between 5 and 150 substrates, or most preferably about 100 substrates. For example, the A412™ may be operated such that one reactor may be used for an anneal process. This may enable to perform long anneals on the order of 1-2 hours in a cost effective way.

The method 100 may also include a third step 130 of performing a selective deposition of a metal or a dielectric film or material on top of either the first DSA polymer or the second DSA polymer. As such, the selective deposition may be done in a way that the deposited film may react selectively with only one of the two polymers. For example, the selective deposition may take place such that the deposited film may react with PMMA polymer and not PS polymer. In accordance with at least one embodiment of the invention, the third step 130 may comprise an atomic layer deposition of the metal or dielectric film.

Furthermore, the selective deposition may be done such that the deposited metal or dielectric film may infiltrate a polymer, while also depositing a second film on the whole volume of the polymer domain. In accordance with at least one embodiment of the invention, the third step 130 may take place in one reactor of an A412 system, such that the second step 120 takes place in the other reactor of the A412 system. It may also be possible that the second step 120 and the third step 130 take place in one single reactor of the A412 system. In addition, a substrate may transferred from a first reaction chamber to a second reaction chamber along with at least a second substrate in a multiple substrate holder. The multiple substrate holder may be capable of holding up 25 substrates or more, 50 substrates or more, 75 substrates or more, or 100 substrates or more.

The metal or dielectric deposited in the third step 130 may comprise aluminum oxide (Al₂O₃), silicon dioxide (SiO₂), silicon nitride (SiN), silicon oxycarbide (SiOC), silicon carbonitride (SiCN), aluminum nitride (AIN), titanium nitride (TiN), tantalum nitride (TaN), tungsten (W), cobalt (Co), titanium dioxide (TiO₂), tantalum oxide (Ta₂O₅), zirconium dioxide (ZrO₂), or hafnium dioxide (HfO₂). In order to perform the selective deposition, precursors to obtain the metal may be used, such as trimethylaluminum (TMA) and water (H₂O) for the formation of Al₂O₃.

The selective deposition in the third step 130 may take place at a temperature ranging between 25° C. and 300° C., with a preferable temperature range of 70° C.-90° C. for the formation of Al₂O₃. The temperature during the third step 130 may be less than the temperature during the second step 120, so a cooldown step may be needed to go from an example annealing temperature of 250° C. to a third step 130 temperature of 70° C. In accordance with at least one embodiment of the invention, a temperature of the second step 120 is at least 25° C. higher than that of the third step 130, preferably between 25° C.-300° C. higher than that of the third step 130, or more preferably between 100° C.-250° C. higher than that of the third step 130.

The third step 130 may comprise a first pulse of a first precursor, such as TMA, for a duration ranging from 30 seconds to 10 minutes. The third step 130 may also then comprise a purge for a duration ranging from 10 to 60 seconds. The third step 130 may then comprise a pulse of a second precursor, such as water, for a duration ranging from 10 to 60 seconds. The third step 130 may then comprise a second purge having a duration ranging from 10 seconds to 2 minutes. In addition, the third step 130 may be repeated as needed in order to obtain sufficient deposition of the metal.

In accordance with at least one embodiment of the invention, the third step 130 of film deposition may precede the second step 120 of annealing. In this case, the metal or dielectric film may first infiltrate the polymer, and then an annealing process may occur. As a result of the annealing process, polymer that did not react with the metal or dielectric film during the third step 130 may be burned away in the second step 120. In at least one embodiment of the invention, the second step 120 of annealing and the third step 130 of film deposition take place without any exposure to ambient air. The lack of exposure to ambient air avoids exposure to substantial amounts of oxygen or water. Exposure to ambient air may adversely affect the alignment of the annealed pattern or infiltration of the polymer, which may be affected by the polymer potentially absorbing water. If the polymer absorbs water, deposition of undesired material may result.

The method 100 may also include a fourth step 140 of purging the precursors. The fourth step 140 may involve introduction of a purge gas such as nitrogen, helium, argon, and other inert gases. The purge gas would remove excess precursor from the fourth step 140 from the processing chamber. The fourth step 140 may take place at a temperature similar to those of the third step 130.

In accordance with at least one embodiment of the invention, the third step 130 may be repeated as necessary in order to allow the precursors to infiltrate into the DSA polymer. The cycle may be repeated approximately 5 times to ensure sufficient amount of the metal or dielectric film in the DSA polymer. In each cycle, the time duration of the third step 130 may be on the order of a few minutes. With these time durations, a batch reactor may be used to achieve high productivity and low process costs by processing up to 100 wafers or more at a time.

In accordance with at least one embodiment of the invention, the method 100 may be operated such that the third step 130 may be repeated in a pulse-purge-pulse-purge manner. The conditions of these steps may be set at higher pressure and a longer time in order to allow the precursors to infiltrate the polymers. A single cycle in this manner may range between 1 and 20 minutes in duration. The cycle may be repeated several times, typically five times, in order to obtain sufficient deposition of the material inside the polymer. Because infiltration of the material inside the polymer may take a longer amount of time, a combined annealing and deposition process provides an opportunity to perform steps in a batch manner.

A potential application for use of a combined annealing and selective deposition process may be for extreme ultraviolet (EUV) photoresist. The annealing for a EUV application may not be for the self-assembly of the polymer, but may serve a curing or stabilizing purpose. For example, the combined annealing and selective deposition process in accordance with at least one embodiment of the invention may assist in the sequential infiltration synthesis (SIS) step as potentially preventing conversion of carboxyl groups, or by degassing moisture from the polymer film or by stabilizing or hardening the photoresist.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various FIGURES are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

What is claimed is:

1. A system configured to selectively form a film comprising:
a first batch reaction chamber, the first batch reaction chamber configured to hold at least one substrate having at least one polymer layer;
a heating element configured to perform an annealing step on the at least one substrate; and
a gas precursor delivery system, the gas precursor delivery system configured to perform a film deposition by sequentially pulsing a first precursor and a second precursor onto the at least one substrate, the film deposition being configured to enable infiltration of at least the first precursor into the at least one polymer layer;
wherein a film or a material forms on the at least one polymer layer; and
wherein the annealing step and the film deposition take place without exposure to ambient air.

2. The system of claim 1, wherein the film comprises at least one of: aluminum oxide (Al₂O₃), silicon dioxide (SiO₂), silicon nitride (SiN), silicon oxynitride (SiON), silicon carbonitride (SiCN), aluminum nitride (AIN), titanium nitride (TiN), tantalum nitride (TaN), tungsten (W), cobalt (Co), titanium dioxide (TiO2), tantalum oxide (Ta₂O₅), zirconium dioxide (ZrO₂), or hafnium dioxide (HfO₂).

3. The system of claim 1, wherein the first batch reaction chamber is configured to process multiple substrates.

4. The system of claim 1, wherein the first batch reaction chamber is configured to perform the annealing step.

5. The system of claim 1, further comprising a batch second reaction chamber configured to hold at least one substrate having at least one polymer layer.

6. The system of claim 5, wherein the first reaction chamber performs the annealing step and the second reaction chamber performs the film deposition.

7. The system of claim 6, wherein the first batch reaction chamber performs the film deposition and the second reaction chamber performs the annealing step.

8. The system of claim 6, wherein the at least one substrate is transferred from the first batch reaction chamber to the second batch reaction chamber along with at least a second substrate in a multiple substrate holder.

9. A system configured to selectively form a film or material comprising:
a first batch reaction chamber, the first batch reaction chamber configured to hold at least a first substrate having at least one polymer layer;
a second batch reaction chamber, the second batch reaction chamber configured to hold at least a second substrate having at least one polymer layer;
a first heating element associated with the first batch reaction chamber and configured to perform an annealing step on the first substrate;
a second heating element associated with the second batch reaction chamber and configured to perform an annealing step on the second substrate; and
a gas precursor delivery system, the gas precursor delivery system configured to deposit a film by sequentially pulsing a first precursor and a second precursor onto the first substrate and the second substrate, wherein at least the first precursor infiltrates into the at least one polymer layer;
wherein the annealing step and the film deposition take place without exposure to ambient air.

10. The system of claim 9, wherein the first reaction chamber is configured to process multiple substrates.

11. The system of claim 9, wherein the second reaction chamber is configured to process multiple substrates.

12. The system of claim 9, wherein the at least one substrate is transferred from the first batch reaction chamber to the second batch reaction chamber along with at least a second substrate in a multiple substrate holder.
